(19) United States
(12) Patent Application Publication
(10) Pub. No.: US 2012/0285738 A1
(43) Pub. Date: Nov. 15, 2012

(54) Shielding Polymers Formed into Lattices Providing EMI Protection for Electronics Enclosures

(76) Inventors: Paul Douglas Cochrane, Durham, NC (US); David Bogart Dort, Alexandria, VA (US)

(21) Appl. No.: 12/860,851

(22) Filed: Aug. 20, 2010

Related U.S. Application Data
(63) Continuation-in-part of application No. 11/770,736, filed on Jun. 29, 2007.
Application No. 11/770,736 is a continuation-in-part of application No. 11/672,943, filed on Feb. 8, 2007, now abandoned.
Application No. 11/672,943 is a continuation of application No. 11/162,887, filed on Sep. 27, 2005, now Pat. No. 7,199,310.
Application No. 11/162,887 is a continuation of application No. 11/012,896, filed on Dec. 15, 2004, now Pat. No. 7,064,265.
(60) Provisional application No. 61/235,454, filed on Aug. 20, 2009.
(60) Provisional application No. 60/593,072, filed on Dec. 7, 2004.

(51) Int. Cl. H05K 9/00; H05K 5/02

(52) U.S. Cl. 174/382; 174/546

(57) ABSTRACT

An electronics enclosure system includes a conductive polymer which includes electromagnetic interference shielding properties and produced to enhancing SE, reducing material costs, and improving thermal flow. “Parallel” hex shaped EMI waveguides placed in a honeycomb pattern are stacked in a staggered fashion with similar hex shaped EMI waveguides placed in a honeycomb pattern. The parallel hex shaped EMI waveguides extend into the interior and/or “cuts” into one or more sides of a an electronics enclosure. An EMI shielding polymer material, such as a coated polymer, or a nickel-fiber carbon polymer such as Primere® providing sufficient EMI shielding (or alternately a material that can be formed such as Superplastic Zinc) is used, having the result that the need for shielding gaskets are reduced, material usage is decreased, and thermal flow is greatly improved.

### REFERENCE TO PRIORITY DOCUMENTS

The present application claims priority under 35 USC 119 to U.S. Provisional Application 61/235,454, filed Aug. 20, 2009 and entitled CONDUCTIVE POLYMER PLATES USING LATTICE CONFIGURATIONS PROVIDING EMI SHIELDING FOR ELECTRONICS ENCLOSURES, which incorporated by reference in its entirety.

The present application also claims under 35 USC §120 priority to, and is a continuation-in-part of, co-pending U.S. application Ser. No. 11/770,736, filed Jun. 29, 2007 and entitled Configurations for EMI Shielding Enclosures, by Paul Douglas Cochrane and David Bogart Dort, which is a continuation-in-part of, claiming priority under 35 USC §120 to, co-pending U.S. application Ser. No. 11/672,943, filed Feb. 8, 2007 and entitled Method for Providing Electromagnetic Interference Shielding in Electronics Enclosures by Forming Tubular Patterns in Conductive Polymer, by Paul Douglas Cochrane which is a continuation pursuant to 35 USC §120 of U.S. application Ser. No. 11/162,887, filed Sep. 27, 2005, now U.S. Pat. No. 7,199,310, issued Apr. 3, 2007, entitled ELECTROMAGNETIC INTERFERENCE SHIELDING STRUCTURES FOR COMPUTER HARD-DRIVE ENCLOSURES, which is a continuation of, and claims priority under 35 USC §120 to, U.S. application Ser. No. 11/012,896, filed Dec. 15, 2004, now U.S. Pat. No. 7,064,265, issued Jun. 20, 2006, which claims priority under 35 USC §119 to U.S. Provisional Application Ser. No. 60/593,072, filed Dec. 7, 2004. All of the above-referenced applications are incorporated by reference herein, for all purposes.

### BACKGROUND

The following background section is, in part, reprinted from “Design Techniques for EMC—Part 4 Shielding” by EurIng Keith Armstrong, Cherry Clough Consultants, Associate of EMC-UK and “EMI Waveguide Apertures” by Intel Corporation.

A complete volumetric shield is often known as a “Faraday Cage”, although this can give the impression that a cage full of holes is acceptable, which it generally is not. There is a cost hierarchy to shielding which makes it commercially important to consider shielding early in the design process. Two additional design considerations that are related to cost are cooling and the shielding effectiveness (SE). Cooling is dependent on the amount of air flow that is allowed to pass through the shielding to the electronic device that is being shielded. SE represents the amount of EMI attenuation that apertures incorporated into the shielding offers for a particular frequency. SE depends on several features of the aperture such as its dimensions (length, width, and height) and the number of apertures. As described below, each of these features affect the shield's design considerations.

A waveguide is essentially a hollow conducting tube that acts as a filter for EMI. Only EMI energy at very high frequencies can pass through it with little attenuation. When used to contain EMI in a chassis enclosure, a waveguide is generally designed such that all frequencies of interest are greatly attenuated by the waveguide. The EMI performance of a waveguide is governed by the surface geometry of the apertures (length and width), the aperture depth, the shape, and total number of apertures.

The metric of waveguide EMI performance is determined by a combination of two parameters: Cutoff Frequency (f_{c}), which determines the maximum possible frequency of effectiveness; and Shielding Effectiveness (SE), which determines the magnitude of the EMI attenuation and is a function of frequency. The f_{c} is the frequency beyond which the waveguide no longer effectively contains EMI. The f_{c} is determined by the outside dimensions of the apertures. SE of a waveguide represents the amount of EMI attenuation that the waveguide offers at a given frequency. This is dependent on several factors. These include the surface geometry of the aperture (length and width), depth, shape of aperture, and the total number of apertures.

A degree of shielding can be achieved by keeping all conductors and components very close to a solid metal sheet. Ground-planed PCBs populated entirely by low-profile surface mounted devices are therefore recommended for EMC advantages.

A useful degree of shielding can be achieved in electronic assemblies firstly, by keeping their internal electronic units and cables very close to an earthed metal surface at all times, and secondly, by bonding their earths directly to the metal surface instead of (or as well as) using a safety star earthing system based on green/yellow wires. This technique usually uses zinc-plated mounting plates or chassis, and can help avoid the need for high values of enclosure SE.

A shield puts an impedance discontinuity in the path of a propagating radiated electromagnetic wave, reflecting it and/or absorbing it. This is conceptually very similar to the way in which filters work—they put an impedance discontinuity in the path of an unwanted conducted signal. The greater the impedance ratio, the greater the SE.

At thicknesses of 0.5 mm or over, most normal fabrication metals provide good SE above 1 MHz and excellent SE above 100 MHz. Problems with metal shields are mostly caused by thin materials, frequencies below 1 MHz, and apertures.

It is generally best to allow a large distance between the circuits that are shielded and the walls of their shield. The emitted fields outside of the shield, and the fields that the devices are subjected to, will generally be more “diluted” the larger the shielded volume.

When enclosures have parallel walls opposite each other, standing waves can build up at resonant frequencies and these can cause SE problems. Irregular shaped enclosures or ones with curved or non-parallel walls will help prevent resonances. When opposing shield walls are parallel, it is desirable to prevent resonances from occurring at the same frequencies due to the width, height, or length. So in order to avoid cubic enclosures, rectangular cross-sections can be used instead of square ones, and try to avoid dimensions that are simple multiples of each other. For example, if the length is 1.5 times the width, the second resonance of the width should coincide with the third resonance of the length. Best to use irrationally ratio'd dimensions, such as those provided by the Fibonacci series.

Fields come in two flavours: electric (E) and magnetic (M). Electromagnetic fields consist of E and M fields in a given ratio (giving a wave impedance E/M of 377.OMEGA. in air). Electric fields are easily stopped by thin metal foils since the mechanism for electric field shielding is one of charge re-distribution at a conductive boundary; therefore, almost anything with a high conductivity (low resistance) will present suitably low impedance. At high frequencies, considerable displacement currents can result from the rapid rate of charge re-distribution, but even thin aluminium can manage this well. However, magnetic fields are much more difficult to stop. They need to generate eddy currents inside the shield material to create magnetic fields that oppose the impinging field. Thin aluminium is not going to be very suitable for this purpose, and the depth of current penetration required for a given SE depends on the frequency of the field. The SE also depends on the characteristics of the metal used for the shield which is known as the “skin effect”.

The skin depth of the shield material known as the “skin effect” causes the currents caused by the impinging magnetic field to be reduced by approximately 9 dB. Hence a material which was as thick as 3 skin depths would have an approximately 27 dB lower current on its opposite side and have an SE of approximately 27 dB for that M field.

The skin effect is especially important at low frequencies where the fields experienced are more likely to be predominantly magnetic with lower wave impedance than 377Ω The formula for skin depth is given in most textbooks; however, the formula requires knowledge of the shielding material's conductivity and relative permeability.

Copper and aluminium have over 5 times the conductivity of steel, so are very good at stopping electric fields, but have a relative permeability of 1 (the same as air). Typical mild steel has a relative permeability of around 300 at low frequencies, falling to 1 as frequencies increase above 100 kHz. The higher permeability of mild steel gives it a reduced skin depth, making the reasonable thicknesses better than aluminium for shielding low frequencies. Different grades of steels (especially stainless) have different conductivities and permeabilities, and their skin depths will vary considerably as a result. A good material for a shield will have high conductivity and high permeability, and sufficient thickness to achieve the required number of skin-depths at the lowest frequency of concern. 1 mm thick mild steel plated with pure zinc (say, 10 microns or more) is suitable for many applications.

It is easy to achieve SE figures of 100 dB or more at frequencies above 30 MHz with ordinary constructional metalwork. However, this assumes a perfectly enclosing shield volume with no joints or gaps, which makes assembly of the product rather difficult unless you are prepared to seam-weld it completely and also have no external cables, antennae, or sensors (rather an unusual product). In practice, whether shielding is being done to reduce emissions or to improve immunity, most shield performance is limited by the apertures within it.

Considering apertures as holes in an otherwise perfect shield implies that the apertures act as half-wave resonant “slot antennae”. This allows us to make predictions about maximum aperture sizes for a given SE: for a single aperture, SE=20 log(.quadrature./2d) where .quadrature is the wavelength at the frequency of interest and d is the longest dimension of the aperture. In practice, this assumption may not always be accurate, but it has the virtue of being an easy design tool that is a good framework. It may be possible to refine this formula following practical experiences with the technologies and construction methods used on specific products.

The resonant frequency of a slot antenna is governed by its longest dimension—its diagonal. It makes little difference how wide or narrow an aperture is, or even whether there is a line-of-sight through the aperture.

Even apertures, the thickness of a paint or oxide film, formed by overlapping metal sheets, still radiate (leak) at their resonant frequency just as well as if they were wide enough to poke a finger through. One of the most important EMC issues is keeping the products' internal frequencies internal, so they don't pollute the radio spectrum externally.

The half-wave resonance of slot antennae (expressed in the above rule of thumb: SE=20 log(.quadrature./2d)) using the relationship .nu.=f.lamda. (where .nu. is the speed of light: 3.10.sup.8 metres/sec, f is the frequency in Hz, and .quadrature. is the wavelength in metres). We find that a narrow 430 mm long gap along the front edge of a 19-inch rack unit's front panel will be half-wave resonant at around 350 MHz. At this frequency, a sample example 19″ front panel is no longer providing much shielding and removing it entirely might not make much difference.

For an SE of 20 dB at 1 GHz, an aperture no larger than around 16 mm is needed. For 40 dB this would be only 1.6 mm, requiring the gaskets to seal apertures and/or the use of the waveguide below cut-off techniques described later. An actual SE in practice will depend on internal resonances between the walls of the enclosure itself, the proximity of components and conductors to apertures (keep noisy cables such as ribbon cables carrying digital busses well away from shield apertures and joints) and the impedances of the fixings used to assemble the parts of the enclosure, etc.

Wherever possible, it is desirable to break all necessary or unavoidable apertures into a number of smaller ones. Unavoidably long apertures (covers, doors, etc) may need conductive gaskets or spring fingers (or other means of maintaining shield continuity). The SE of a number of small identical apertures nearby each other is (roughly) proportional to their number (SE=20 log n, where n is the number of apertures), so two apertures will be worse by 6 dB, four by 12 dB, 8 by 18 dB, and so on. But when the wavelength at the frequency of concern starts to become comparable with the overall size of the array of small apertures, or when apertures are not near to each other (compared with the wavelength), this crude 6 dB per doubling rule breaks down because of phase cancellation effects.

Apertures placed more than half a wavelength apart do not generally worsen the SEs that achieves individually, but half a wavelength at 100 MHz is 1.5 metres. At such low frequencies on typical products smaller than this, an increased number of apertures will tend to worsen the enclosure's SE.

Apertures don't merely behave as slot antennae. Currents flowing in a shield and forced to divert their path around an aperture will cause it to emit magnetic fields. Voltage differences across an aperture will cause the aperture to emit electric fields. The author has seen dramatic levels of emissions at 130 MHz from a hole no more than 4 mm in diameter (intended for a click-in plastic mounting pillar) in a small PCB-mounted shield over a microcontroller.

The only really sensible way to discover the SE of any complex enclosure with apertures is to model the structure, along with any PCBs and conductors (especially those that might be near any apertures) with a 3-dimensional field solver. Software packages that can do this now have more user-friendly interfaces and run on desktop PCs. Alternatively, you will be able to find a university or design consultancy that has the necessary software and the skills to drive it.

Since an SE will vary strongly with the method and quality of assembly, materials, and internal PCBs and cables, it is always best to allow yourself an SE ‘safety margin’ of 20 dB. It may also be best to allow yourself at least design-in features that will allow you to improve the SE by at least 20 dB if you have problems with the final design's verification/qualification testing.

The frequency of 50 Hz is problematic, and SE at this frequency with any reasonable thickness of ordinary metals is desirable. Special materials such as Mumetal and Radiometal have very high relative permeabilities, often in the region of 10,000. Their skin depth is correspondingly very small, but they are only effective up to a few tens of kHz. Care must be taken not to knock items made of these materials, as this ruins their permeability and they have to thrown away or else re-annealed in a hydrogen atmosphere. These exotic materials are used rather like channels to divert the magnetic fields away from the volume to be protected. This is a different concept to that used by ordinary shielding.

All metals shield materials with relative permeability greater than 1 can saturate in intense magnetic fields, and then don't work well as shields and often heat up. A steel or Mumetal shield box over a mains transformer to reduce its hum fields can saturate and fail to achieve the desired effect. Often, all that is necessary is to make the box larger so it does not experience such intense local fields. Another shielding technique for low frequency shielding is active cancellation, and at least two companies have developed this technique specifically for stabilizing the images of CRT VDUs in environments polluted by high levels of power frequency magnetic fields.

FIG. 7A shows that if we extend the distance that a wave leaking through an aperture has to travel between surrounding metal walls before it reaches freedom, we can achieve respectable SEs even thought the apertures may be large enough to put your fist through. This very powerful technique is called “waveguide below cut-off”. Honeycomb metal constructions are really a number of waveguides below cut-off stacked side-by-side, and are often used as ventilation grilles for shielded rooms, similar to high-SE enclosures.

Like any aperture, a waveguide allows all its impinging fields to pass through when its internal diagonal (g) is half a wavelength. Therefore, the cut-off frequency of our waveguide is given by: f.sub.cutoff=150,000/g (answer in MHz when g is in mm.) Below its cut-off frequency, a waveguide does not leak like an ordinary aperture (as shown by FIG. 4H) and can provide a great deal of shielding: for f<0.5f.sub.cutoff SE is approximately 27d/g where d is the distance through the waveguide the wave has to travel before it is free.

FIG. 1A shows examples of the SE achieved by six different sizes of waveguides below cut-off. Smaller diameter (g) results in a higher cut-off frequency, with a 50 mm (2 inch) diameter achieving full attenuation by 1 GHz. Increased depth (d) results in increased SE, with very high values being readily achieved.

Waveguides below cut-off do not have to be made out of tubes, and can be realized using simple sheet metalwork which folds the depth (d) so as not to increase the size of the product by much. As a technique it is only limited by the imagination, but it must be taken into consideration early in a project as it is usually difficult to retrofit to a failing product not intended to use it. Conductors should never be passed through waveguides below cut-off, as this compromises their effectiveness. Waveguides below cut-off can be usefully applied to plastic shafts (e.g. control knobs) so that they do not compromise the SE where they exit an enclosure. The alternative is to use metal shafts with a circular conductive gasket and suffer the resulting friction and wear. Waveguides below cut-off can avoid the need for continuous strips of gasket, and/or for multiple fixings, and thus save material costs and assembly times.

Gaskets are used to prevent leaky apertures at joints, seams, doors and removable panels. For fit-and-forget assemblies, gasket design is not too difficult, but doors, hatches, covers, and other removable panels create many problems for gaskets, as they must meet a number of conflicting mechanical and electrical requirements, not to mention chemical requirements (to prevent corrosion). Shielding gaskets are sometimes required to be environmental seals as well, adding to the compromise.

FIG. 1B shows a typical gasket design for the door of an industrial cabinet, using a conductive rubber or silicone compound to provide an environmental seal as well as an EMC shield. Spring fingers are often used in such applications as well.

A huge range of gasket types is available from a number of manufacturers, most of whom also offer customizing services. This observation reveals that no one gasket is suitable for a wide range of applications. Considerations when designing or selecting gaskets include: (1) mechanical compliance, (2) compression set, (3) impedance over a wide range of frequencies, (4) resistance to corrosion (low galvanic EMFs in relation to its mating materials, appropriate for the intended environment), (5) ability to withstand the expected rigours of normal use, (6) shape and preparation of mounting surface, (7) ease of assembly and dis-assembly, (8) environmental sealing, and smoke and fire requirements.

There are four main types of shielding gaskets: (1) conductive polymers (insulating polymers with metal particles in them). These double as environmental seals, have low compression set but need significant contact pressure, making them difficult to use in manually-opened doors without lever assistance; (2) conductively wrapped polymers (polymer foam or tube with a conductive outer coating); These can be very soft and flexible, with low compression set. Some only need low levels of contact pressure. However, they may not make the best environmental seals and their conductive layer may be vulnerable to wear; (3) metal meshes (random or knitted) are generally very stiff but match the impedance of metal enclosures better and so have better SEs than the above types. They have poor environmental sealing performance, but some are now supplied bonded to an environmental seal, so that two types of gaskets may be applied in one operation; (4) spring fingers (“finger stock”) are usually made of beryllium copper or stainless steel and can be very compliant. Their greatest use is on modules (and doors) which must be easy to manually extract (open), easy to insert (close), and which have a high level of use. Their wiping contact action helps to achieve a good bond, and their impedance match to metal enclosures is good, but when they don't apply high pressures, maintenance may be required (possibly a smear of petroleum jelly every few years). Spring fingers are also more vulnerable to accidental damage, such as getting caught in a coat sleeve and bending or snapping off. The dimensions of spring fingers and the gaps between them causes inductance, so for high frequencies or critical use a double row may be required, such as can be seen on the doors of most EMC test chambers.

Gaskets need appropriate mechanical provisions made on the product to be effective and easy to assemble. Gaskets simply stuck on a surface and squashed between mating parts may not work as well as is optimal—the more their assembly screws are tightened in an effort to compress the gasket and make a good seal, the more the gaps between the fixings can bow, opening up leaky gaps. This is because of inadequate stiffness in the mating parts, and it is difficult to make the mating parts rigid enough without a groove for the gasket to be squashed into, as shown by FIG. 1B. This groove also helps correctly position and retains the gasket during assembly.

Gasket contact areas must not be painted (unless it is with conductive paint), and the materials used and their preparation and plating must be carefully considered from the point of view of galvanic corrosion. All gasket details and measures must be shown on manufacturing drawings, and all proposed changes to them assessed for their impact on shielding and EMC. It is not uncommon, when painting work is transferred to a different supplier, for gaskets to be made useless because masking information was not put on the drawings. Changes in the painting processes used can also have a deleterious effect (as can different painting operatives) due to varying degrees of overspray into gasket mounting areas which are not masked off.

FIG. 7C shows a large aperture in the wall of the shielded enclosure, using an internal “dirty box” to control the field leakage through the aperture. The joint between the dirty box and the inside of the enclosure wall must be treated the same as any other joint in the shield.

A variety of shielded windows are available, based on two main technologies: (1) thin metal films on plastic sheets, usually indium-tin-oxide (ITO). At film thicknesses of 8 microns and above, optical degradation starts to become unacceptable, and for battery-powered products, the increased backlight power may prove too onerous. The thickness of these films may be insufficient to provide good SEs below 100 MHz; (2) embedded metal meshes, usually a fine mesh of blackened copper wires. For the same optical degradation as a metal film, these provide much higher SEs, but they can suffer from Moire fringing with the display pixels if the mesh is not sized correctly. One trick is to orient the mesh diagonally.

Honeycomb metal display screens are also available for the very highest shielding performance. These are large numbers of waveguides below cut-off, stacked side by side, and are mostly used in security or military applications. The extremely narrow viewing angle of the waveguides means that the operator's head prevents anyone else from sneaking a look at their displays.

The mesh size must be small enough not to reduce the enclosure's SE too much. The SE of a number of small identical apertures near to each other is (roughly) proportional to their number, n, (SE 20 log n), so two apertures will make SE worse by 6 dB, four by 12 dB. 8 by 18 dB, and so on. For a large number of small apertures typical of a ventilation grille, mesh size will be considerably smaller than one aperture on its own would need to be for the same SE. At higher frequencies where the size of the ventilation aperture exceeds one-quarter of the wavelength, this crude “6 dB per doubling” formula can lead to over-engineering, but no simple rule of thumb exists for this situation.

Waveguides below cut-off allow high air flow rates with high values of SE. Honeycomb metal ventilation shields (consisting of many long narrow hexagonal tubes bonded side-by-side) have been used for this purpose for many years. Honeycomb ventilation shields can also be made from polymers. Through the addition of metal, or metal coated constituents to the polymer resins, EMI attenuation using injection molded plastic parts has become a very viable and in many ways advantageous alternative. One of the most desirable materials for this purpose is the material PREMIER® made by Chomerics of Woburn, Mass. This material provides nickel-plated fibrous carbon material, in a preferred embodiment which is appropriate for EMI shielding, but also can be efficiently and economically manufactured in the configurations required by the present invention.

The design of shielding for ventilation apertures can be complicated by the need to clean the shield of the dirt deposited on it from the air. Careful air filter design can allow ventilation shields to be welded or otherwise permanently fixed in place.

Plastic enclosures are often used for a pleasing feel and appearance, but can be difficult to shield. Coating the inside of the plastic enclosure with conductive materials such as metal particles in a binder (conductive paint), or with actual metal (plating), is technically demanding and requires attention to detail during the design of the mould tooling if it is to stand a chance of working.

It is often found, when it is discovered that shielding is necessary, that the design of the plastic enclosure does not permit the required SE to be achieved by coating its inner surfaces. The weak points are usually the seams between the plastic parts; they often cannot ensure a leak-tight fit, and usually cannot easily be gasketted. Expensive new mould tools are often needed, with consequent delays to market introduction and to the start of income generation from the new product.

Whenever a plastic case is required for a new product, it is financially vital that consideration be given to achieving the necessary SE right from the start of the design process.

Paint or plating on plastic can never be very thick, so the number of skin-depths achieved can be quite small. Some clever coatings using nickel and other metals have been developed to take advantage of nickel's reasonably high permeability in order to reduce skin depth and achieve better SE.

Other practical problems with painting and plating include making them stick to the plastic substrate over the life of the product in its intended environment. Not easy to do without expert knowledge of the materials and processes. Conductive paint or plating flaking off inside a product can do a lot more than compromise EMC—it can short out conductors, causing unreliable operation and risking fires and electrocution. Painting and plating plastics must be done by experts with long experience in that specialized field.

A special problem with painting or plating plastics is voltage isolation. For class II products (double insulated), adding a conductive layer inside the plastic cases can reduce creepage and clearance distances and compromise electrical safety. Also, for any plastic-cased product, adding a conductive layer to the internal surface of the case can encourage personnel electrostatic discharge (ESD) through seams and joints, possibly replacing a problem of radiated interference with the problem of susceptibility to ESD. For commercial reasons, it is important that careful design of the plastic enclosure occurs from the beginning of the design process if there is any possibility that shielding might eventually be required.

Some companies box cleverly (pun intended) by using thin and unattractive low-cost metal shields on printed circuit boards or around assemblies, making it unnecessary for their pretty plastic case to do double duty as a shield. This can save a great deal of cost and headache, but must be considered from the start of a project or else there will be no room available (or the wrong type of room) to fit such internal metalwork.

Volume-conductive plastics or resins generally use distributed conductive particles or threads in an insulating binder which provides mechanical strength. Sometimes these suffer from forming a “skin” of the basic plastic or resin, making it difficult to achieve good RF bonds without helicoil inserts or similar means. These insulating skins make it difficult to prevent long apertures which are created at joints, and also make it difficult to provide good bonds to the bodies of connectors, glands, and filters. Problems with the consistency of mixing conductive particles and polymer can make enclosures weak in some areas, and lacking in shielding in others.

Materials based on carbon fibres (which are themselves conductive) and self-conductive polymers are starting to become available, but they do not have the high conductivity of metal and so do not give as good an SE for a given thickness. The screens and connectors (or glands) of all screened cables that penetrate a shielded enclosure, and their 360.degree. bonding, are as vital a part of any “Faraday Cage” as the enclosure metalwork itself. The thoughtful assembly and installation of filters for unshielded external cables is also vital to achieve a good SE. Refer to the draft IEC1000-5-6 (95/210789 DC from BSI) for best practices in industrial cabinet shielding (and filtering). Refer to BS IEC 61000-5-2:1998 for best practices in cabling (and earthing).

Returning to our original theme of applying shielding at as low a level of assembly as possible to save costs, we should consider the issues of shielding at the level of the PCB. The ideal PCB-level shield is a totally enclosing metal box with shielded connectors and feedthrough filters mounted in its walls, really just a miniature version of a product-level shielded enclosure as described above. The result is often called a module which can provide extremely high SEs, and is very often used in the RF and microwave worlds.

Lower cost PCB shields are possible, although their SE is not usually as good as a well-designed module. All depend upon a ground plane in a PCB used to provide one side of the shield, so that a simple five-sided box can be assembled on the PCB like any other component. Soldering this five-sided box to the ground plane at a number of points around its circumference creates a “Faraday cage” around the desired area of circuitry. A variety of standard five-sided PCB-mounted shielding boxes are readily available, and companies who specialize in this kind of precision metalwork often make custom designs. Boxes are available with snap-on lids so that adjustments may easily be made, test points accessed, or chips replaced, with the lid off. Such removable lids are usually fitted with spring-fingers all around their circumference to achieve a good SE when they are snapped in place.

Weak points in this method of shielding are obviously the apertures created by the gaps between the ground-plane soldered connections, any apertures in the ground plane (for example clearances around through-leads and via holes), and any other apertures in the five-sided box (for example ventilation, access to adjustable components, displays, etc.) Seam-soldering the edges of a five-sided box to a component-side ground plane can remove one set of apertures, at the cost of a time-consuming manual operation.

The PCB track equivalent of a shielded cable is a track run between two ground planes, often called a “stripline.” Sometimes guard tracks are run on both sides of this “shielded track” on the same copper layer. These guard tracks have very frequently via holes bonding them to the top and bottom ground planes. The number of via holes per inch is the limiting factor here, as the gaps between them act as shield apertures (the guard tracks have too much inductance on their own to provide a good SE at high-frequencies). Since the dielectric constant of the PCB material is roughly four times that of air, their frequency axes should be divided by two (the square root of the PCB's dielectric constant). Some designers don't bother with the guard tracks and just use via holes to “channel” the track in question. It may be a good idea to randomly vary the spacings of such rows of via holes around the desired spacing in order to help avoid resonances.

Where striplines enter an area of circuitry enclosed by a shielded box, it is sufficient that their upper and lower ground planes (and any guard tracks) are bonded to the screening can's soldered joints on both sides close to the stripline.

The track which only has a single ground plane layer in parallel, the other side being exposed to the air, is said to be of “microstrip” construction. When a microstrip enters a shielded PCB box, it will suffer an impedance discontinuity due to the wall of the box. If the wavelength of the highest frequency component of the signals in the microstrip is greater than 100 times the thickness of the box wall (or the width of box mounting flange), the discontinuity may be too brief to register. But where this is not the case, some degradation in performance may occur and such signals are best routed using striplines.

All unshielded tracks must be filtered as they enter a shielded PCB area. It is often possible to get valuable improvements using PCB shielding without such filtering, but this is difficult to predict. Therefore, filtering should always be designed-in (at least on prototypes, only being removed from the PCB layout after successful EMC testing).

The best filters are feedthrough types, but to save cost we need to avoid wired tynes. Leaded PCB-mounting types are available and can be soldered to a PCB in the usual manner. Then the leaded PCB mount is hand-soldered to the wall of the screening box when it is fitted at a later stage. Quicker assembly can be achieved by soldering the central contact of the filter to the underlying ground plane, making sure that solder joints between the shielding box and the same ground plane layer are close by on both sides. This latter construction also suits surface-mounted “feed-through” filters, further reducing assembly costs. But feed-through filters, even surface mounted types, are still more expensive than simple ferrite beads or capacitors. To allow the most cost-effective filters to be found during development EMC testing, whilst also minimizing delay and avoiding PCB layout iterations, multipurpose pad patterns can easily be created to take any of the following filter configurations zero-ohm link (no filtering, often used as the starting point when EMC testing a new design); (2) a resistor or ferrite bead in series with the signal; a capacitor to the ground plane; (4) common-mode chokes; (5) resistor/ferrite/capacitor combinations (tee, LC, etc.); (6) feed-through capacitor (i.e. centre-pin grounded, not truly feed-through); (7) feedthrough filter (tee)LC, etc., centre-pin grounded, not truly feedthrough). Multipurpose padding also means we are not restricted to proprietary filters and can create our own to best suit the requirements of the circuit (and the product as a whole) at the lowest cost.

Also of note, in the literature in the discussion of the attempt to reduce shielding gaskets in an electronics enclosure is the study and publication: “Alternatives to Gaskets in Shielding an Enclosure” by Centola, Pommenke, Kai and Drewiak, of the University of Missouri at Rolle, Copyright IEEE 2002, and available from the IEEE. In this article the authors discuss the effectiveness of “overlapping” structures as alternatives to gasketting. This publication is incorporated by reference for all purposes.

### SUMMARY

The present invention provides a configuration of a electronic enclosures and method for manufacturing in which a polymer including an electromagnetic interference shielding (EMI shielding) is configured such that shielding gaskets may be reduced or eliminated completely while enhancing SE, reducing material costs, and improving thermal flow. Parallel hex shaped EMI waveguides that are placed in a honeycomb pattern are stacked in a staggered fashion with similar hex shaped EMI waveguides placed in a honeycomb pattern. The parallel hex shaped EMI waveguides extend into the interior and/or “cuts” into one or more sides of a disk-drive holder made of an EMI shielding polymer material, such as a coated polymer or a nickel-fiber carbon polymer such as Primere®, providing sufficient EMI shielding (or alternately a material that can be formed such as Superplastic Zinc), having the result that the need for shielding gaskets are reduced, material usage is decreased, and thermal flow is greatly improved. In an alternate configuration of the invention, a computer box is provided with an inexpensive shielding solution

### BRIEF DESCRIPTION OF THE DRAWINGS

FIG. 1A is an illustration of an electronics enclosure, particularly for a computer hard disk drive, made of a conductive or coated polymer form a front-top view;

FIG. 1B is an illustration of the electronics enclosure from the rear-side view;

FIG. 1C is the illustration of the electronics enclosure from a front view;

FIG. 1D is a detail view of an electronic enclosure from a rear-bottom view;

FIG. 2 is a sample single hexagonal waveguide;

FIG. 3A illustrates alternate embodiment of the faceplate (as shown in FIGS. 1A-D) with the tubular members “cut” to a shortened depth;

FIG. 3B illustrates a version of the ‘shared wall’ embodiment of the matrix shown in a honeycomb configuration;

FIG. 3C illustrates a detailed version of the ‘shared wall’ embodiment of the front plate illustrated in FIG. 3A;

FIG. 4A illustrates a ‘staggered honeycomb’ embodiment of the EMI-shielding front plate;

FIG. 4B illustrates an overall view of the ‘staggered honeycomb’ embodiment of the EMI-shielding front plate from an opposite angle;

FIG. 4C illustrates the ‘staggered honeycomb’ embodiment of the EMI-shielding front plate from a frontal view;

FIG. 5 illustrates the ‘staggered honeycomb’ embodiment and properties of waves in the interior;

FIG. 6 illustrates a multiple plane staggered honeycomb embodiment with various features; and

FIGS. 7A-E illustrates some electromagnetic interference shielding principles as discussed in the background section;

### DETAILED DESCRIPTION OF THE INVENTION

Shielding is the use of conductive materials to reduce EMI by reflection or absorption. Shielding electronic products successfully from EMI is a complex problem with three essential ingredients: a source of interference, a receptor of interference, and a path connecting the source to the receptor. If any of these three ingredients is missing, there is not an interference problem. Interference takes many forms such as distortion on a television, disrupted/lost data on a computer, or “crackling” on a radio broadcast. The same equipment may be a source of interference in one situation and a receptor in another.

Currently, the FCC regulates EMI emissions between 30 MHz and 2 GHz (and is currently expected to go much higher), but does not specify immunity to external interference. As device frequencies increase (applications over 10 GHz are becoming common), their wavelengths decrease proportionally, meaning that EMI can escape/enter very small openings (for example, at a frequency of 1 GHz, an opening must be less than ½ an inch). The trend toward higher frequencies therefore is helping drive the need for more EMI shielding. As a reference point, computer processors operate in excess of 250 MHz and some newer portable phones operate at 900 MHz. However, the principles involved in the invention clearly provide for EMI emissions that go much higher than 2 GHz.

Metals (inherently conductive) traditionally have been the material of choice for EMI shielding. In recent years, there has been a tremendous surge in plastic resins (with conductive coatings or fibers) replacing metals due to plastics many benefits. Even though plastics are inherently transparent to electromagnetic radiation, advances in coatings and fibers have allowed design engineers to consider the merits of plastics.

As a specific example, considering the FCC regulation to shield up to 2 GHz, a typical maximum clock speed in many of the controllers in the enterprise networks would be 400 MHz. If you consider the 2 GHz value as the maximum frequency of interest, then at 400 MHz you are saying that you will shield up to and including the 5th harmonic of a 400 MHz signal . . . i.e. 400 MHz*5=2 GHz (shielding to the 5th harmonic of maximum clock speed of 400 MHz).

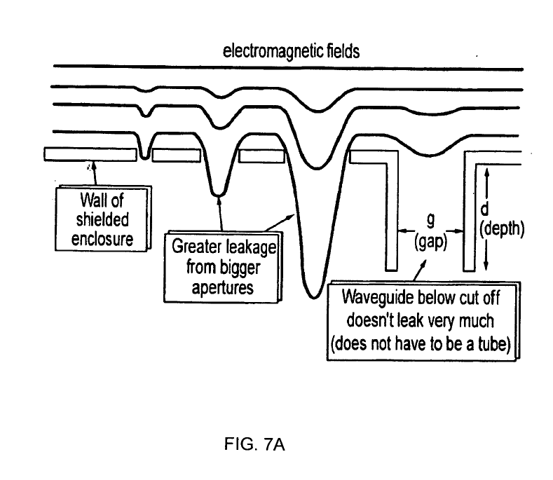

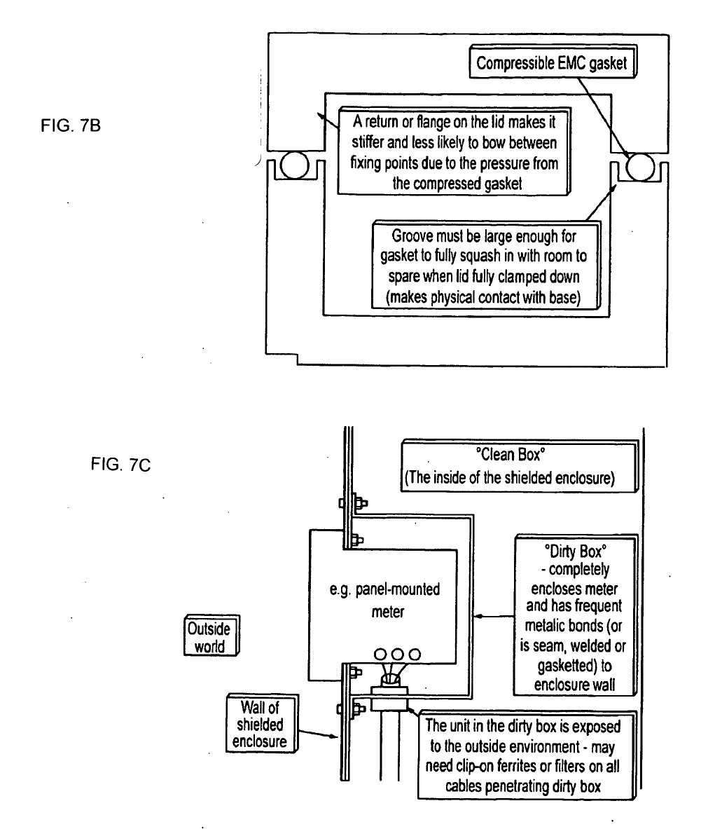

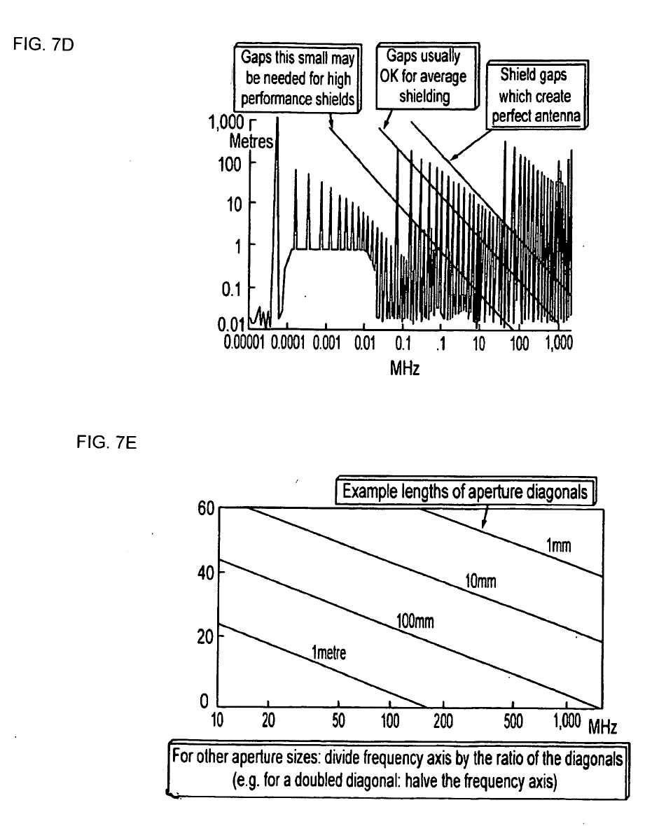

The half-wave resonance of slot antennae, expressed in the above rule of thumb, is the basis for the solid line in FIG. 7D (and for the rule-of-thumb of FIG. 7E) using the relationship: SE=20 log(λ./2d). Therefore the degradation associated with a multiple hole pattern is given by: SE reduction=10 log(N), where N=the # of holes in the pattern. Using the relationship: f.lamda.=c, where is c the speed of light: 3.times.10̂8 msec, the frequency in Hz, and .lamda. is the wavelength in meters, where: f=the frequency of the wave .lamda.=the wavelength, c=the speed of light.

To determine the wavelength at 2 GHz, utilize equation C, above: f.lamda.=c, .lamda.=c/f .lamda.=(3.times.108)/(2*109 .lamda.=0.15 meters (at 2 GHz). Terms A & B are of interest with regard to the determination of a longest possible slot length .lamda./2=0.075 m or 75 mm. It is recommended that the apertures be kept to a range of approximately .lamda./20 to .lamda./50, therefore for 2 GHz, the apertures should be in the range of: .lamda./20=0.0075 meters or 7.5 mm maximum @ 2 GHz; .lamda./50=0.003 meters or 3.0 mm minimum @ 2 GHz.

Looking to equation from above, the shielding effectiveness for 1 hole of maximum length “X”: SE=20 log(.lamda./2d) (there is no minimum—the smaller the better. This equation is used as a practical value for packaging.) @ 3 mm--->SE=20 log(0.15/(20.003))=20 log(25)=28 dB'@ 7.5 mm--->SE=20 log(0.15/(20.0075))=20 log(10)=20 dB

Therefore, in a standard application where there are multiple holes—for example, a perfed 0.060″ thick steel faceplate SE reduction=10 log(N) with a hole pattern of comprised of 100 holes. SE reduction=10 log(N)=10 log(100)=20. The result is that this will reduce the shielding to zero in the case of the 7.5 mm holes and it will reduce the shielding to 8 dB in the case of the 3 mm holes.

Hence, the restrictive nature of EMI shielding emerges when considered with the interplay between getting cooling air in without letting magnetic interference out and is addressed by the various embodiments of the invention in which honeycomb and other tubular structures, U-seams, and waveguides formed in efficient materials, such as conductive (or coated) plastics are a desirable solution (but in some embodiments can also be formed in metals, or materials like superplastic zinc).

It is recommended that most packaging applications provide .about.15 dB of shielding at the enclosure level. As is evident from the above information, this is far from easy to accomplish without an advance in the technology. It should be noted that the degradation described above does not even consider all the losses at seams where the gaskets are actually used. This is only the “perf” for airflow.

Waveguide EMI performance is governed by the surface geometry of the apertures (length and width), the aperture depth, the shape, and total number of apertures. EMI performance is determined by two parameters: cutoff frequency, which determines the maximum possible frequency of effectiveness and SE, which determines the magnitude of the EMI attenuation and is a function of frequency. Material costs and thermal efficiency must also be considered when designing the shielding.

Cutoff frequency depends on the outside dimensions of the aperture. Increasing the aperture size decreases f_{c}, and decreasing the aperture size increases f_{c}. SE is effected by the number of apertures located in the shield. A change from N to 2N in a waveguide panel decreases the SE by approximately 3 dB for frequencies below the f_{c}. SE is also effected by the depth of the apertures. Increasing the depth of the aperture increases SE but decreases thermal flow. The present design considers all these factors when designing EMI shielding. SE is improved, cutoff frequency is lowered, material cost is reduced, and thermal efficiency is increased by utilizing parallel hex shaped EMI waveguides placed in a honeycomb pattern made of an EMI shielding polymer material.

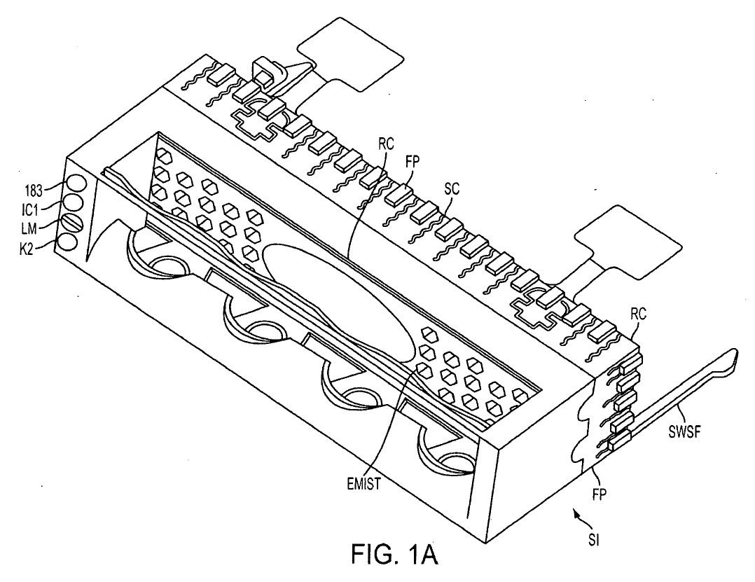

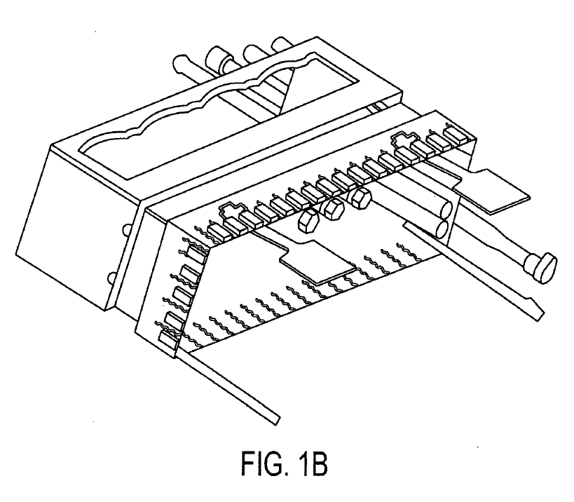

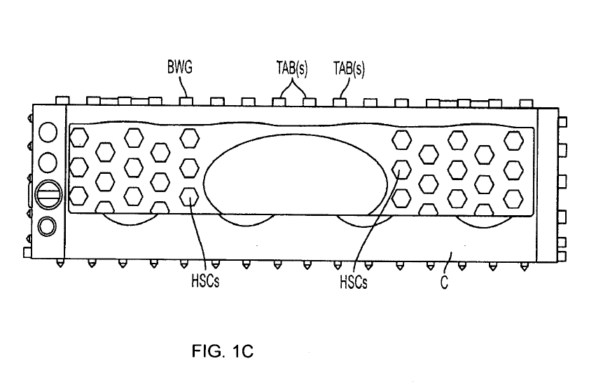

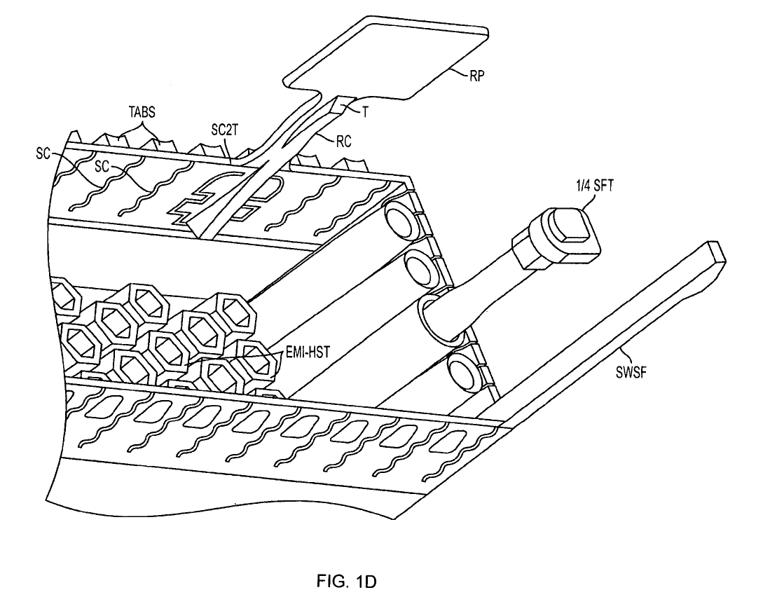

In order to implement some of the shielding solution discussed above for electronics and more specifically for hard disk drives, FIG. 1A shows a top-front overview of a first embodiment of a front plate assembly 10 used for protection of the hard drive systems and providing sufficient electromagnetic interference (EMI) shielding. The front plate assembly 10 includes two separately manufacture-able portions, each of which generally respectively be made of two distinct materials providing two different functions.

A front cosmetic cover C is shown and can made of inexpensive plastic-molded polymer, which would be appropriate for use in such a cosmetic part. The cosmetic material cover C material will not provide any particular advantage regarding function of the EMI shielding solution, but is provided in order to keep the costs of the manufacturing material lower, as the front plate FP portion of the assembly will be made of an EMI shielding polymer, whether conductive or coated with a metal in a preferred embodiment and, in general, will be much more expensive than the cosmetic cover C material. Although the cosmetic cover C is made of a less expensive plastic material, in optional embodiments of the invention, the cosmetic cover structure C serves an important purpose in providing a locking system LM, and optional indicators IC1, IC2, IC3, which have structures that extend into the interior part of the front plate FP.

In general, the front plate FP part of the assembly, in a preferred embodiment of the invention is an appropriate polymer that provides EMI protection. One of the most desirable materials for this purpose is the material PREMIER® made by Chomerics of Woburn, Mass. This material provides nickel-plated fibrous carbon material, in a preferred embodiment which is appropriate for EMI shielding, but also can be efficiently and economically manufactured in the configurations required by the present invention. Also, the specifications regarding this material are available from the manufacturer, as are specifications regarding materials such as Superplastic Zinc.

The use of composite media for EMI shielding at microwave frequencies has been discussed. For example, the use of analytical and numerical modeling of composites with an isotropic dielectric base and multiphase conducting inclusions for the development of wideband microwave shields is shown in “Engineering of Composite Media for Shields at Microwave Frequencies” (“Microwave”) by Koledintseva et al. and incorporated by reference hereinto. Microwave shows the use of Maxwell Garnett formalism for multiphase mixtures for the design of shields for electromagnetic compatibility purposes for electronic devices.

The front panel FP of the face plate is shown in a matrix pattern of “shaped tubes”, shown as a honeycomb tubes in FIGS. 1A-C, but may be tubes of any of a combination of shapes as discussed above, with the tubes EMI-IST traveling through the wall of the front of the panel P1. The honeycomb pattern is used in a preferred embodiment. However any configurations on the front panel P1 of the face plate may include other types of cuts or structures EMI-IST that are perpendicular to and therefore provide sufficient shielding in the direction of the wave propagation. Other configurations that provide reduced or “no gasket” solutions with sufficient EMI shielding are discussed more fully below.

FIG. 1C illustrates a rear side view of a preferred embodiment of the invention, and further shows the structural tubes that continue from the front of the front plate FP to the interior.

FIG. 1B shows a front view of the front plate FP assembly 10 that protects the electronic device while providing sufficient EMI shielding. The cosmetic front portion of the assembly C is shown as “housing” the EMI portion, of which is shown to be a “honeycomb” front piece with a specimen logo. The honeycomb front piece is cut or preferably molded with a shielding pattern which resembles “honeycomb” tubes or holes HSCs in a preferred embodiment. Although hex honeycomb shielding cuts HSCs are shown in FIG. 1B, other tubular patterns or multiple patterns may be used, such as circles, squares, pentagons, octagons, etc.

A different embodiment of the invention include a method for reducing or eliminating electromagnetic interference gasket shielding in an electronics enclosure by providing a front panel made of an appropriate polymer for sufficient electromagnetic shielding of an electronics enclosure and cutting a series of shallow tubes in said front panel in a honeycomb or a matrix pattern of tubular shapes, such that there are a plurality of tubes. Generally, the “tubular” shapes will extend further behind the plane of the front part of the back wall and extending into the interior of the enclosure, however many embodiments discussed below use other techniques to preserve valuable material and improve thermal flow. The tubular shapes not only provide sufficient EMI shielding and improved thermal ventilation, but also provide the ability to manufacture the enclosure with sufficient structural stability.

Additionally, as shown in FIGS. 1A-C, an optional set of first interruption patterns are cut a into the circumference of the body of the holder extending backward from the front plane. The body may be made of metal in some embodiments, but is made of an appropriate coated or conductive polymer, the conductive polymer preferably includes nickel-plated carbon fibers, such as Premier® by Chomerics other potentially appropriate materials include moldable polymers, or “drawable” Superplastic Zinc and even metal-coated conductive polymers (although it is contemplated that coating is too an expensive process for many of the embodiments).

In various assembly embodiments, the invention may be a reduced-gasket assembly for protecting or containing an electronic device that includes a polymer or metal body formed of a material that provides for sufficient electromagnetic interference (EMI) shielding. The front panel of the body is configured with a set of interference shielding structures. In target embodiments, the set of shielding structures form a matrix of hexagonal apertures placed in a honeycomb pattern where the hexagonal apertures share its walls with the other hexagonal apertures, stacked in a staggered fashion with a similar hexagonal matrix formed in a honeycomb pattern. The honeycomb shielding may be stacked abutting each other or with spacing depending on the thermal constraints of the application. It is most desirable that no gaskets are present to provide the EMI shielding, and the EMI shielding material forming the front plate FP includes nickel-plated carbon and preferably Premier®.

The invention may also be viewed as a method for manufacturing an electromagnetic interference (EMI) shielding assembly as recited above, where the front plate FP is formed from a plastic mold injection system for reduced-cost manufacturing. In one embodiment, the invention is a reduced-gasket assembly for protecting a electronic device, including a polymer, or optionally, a body formed of a material that provides for sufficient electromagnetic interference (EMI) shielding, that includes a front panel configured with a set of interference shielding structures that form a matrix of hexagonal apertures placed in a honeycomb pattern where the hexagonal apertures share its inner walls IW with the other hexagonal apertures. The invention may be embodied as an assembly for holding a electronic device providing electromagnetic interference (EMI) shielding, including a cosmetic front and a front plate FP capable of securely fitting into said cosmetic front, and formed from a polymer providing sufficient EMI shielding, configured to include a EMI shielding structures cut or formed into the front panel of the front plate FP.

The cosmetic front C is made from a second type of material that includes a polymer, said polymer not providing EMI shielding. The front plate FP includes nickel-plated carbon and preferably Premier® that provides the EMI shielding. The cosmetic front includes an operational structure for a quarter-turn locking mechanism.

Pressure drop is a quantity of interest in the analysis of air flow in a tube. The pressure drop (P) during the flow in a tube of length (L) is expressed as: P=f[(LpVₘ²)/(2D)], where f is the friction factor, Vₘ is the mean velocity of the air, p is the density of the air, and D is the diameter of the tube. As shown in the above equation there is a direct relationship between pressure drop from the entrance to the exit of a tube and the length of that tube. This direct relationship causes an increased pressure drop and thus decreased air flow, with an increase in tube length. However, there is a tradeoff between improved SE and increased depth with material used and air flow to the electronic device. Air flow to the electronic device is dependent on the pressure drop between the inlet and outlet of the apertures in the shielding. The pressure drop of the shielding is dependent on the geometry of the apertures incorporated into the shielding (percent open area, hole shape, hole depth, aperture size, and the number of apertures in the shielding). With all other factors being equal, increasing the depth of an aperture increases the SE, but restricts airflow to the electronic device and requires more material to be used.

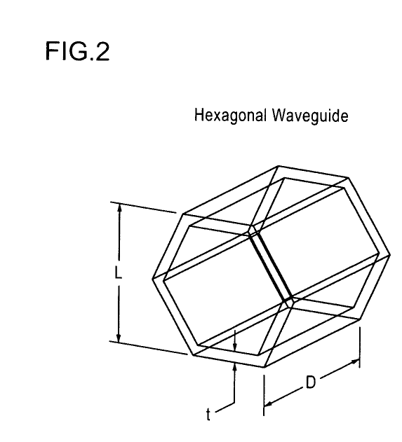

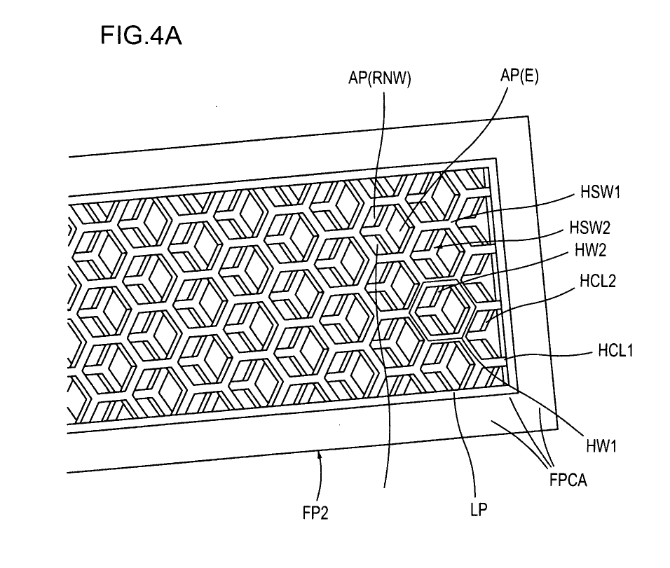

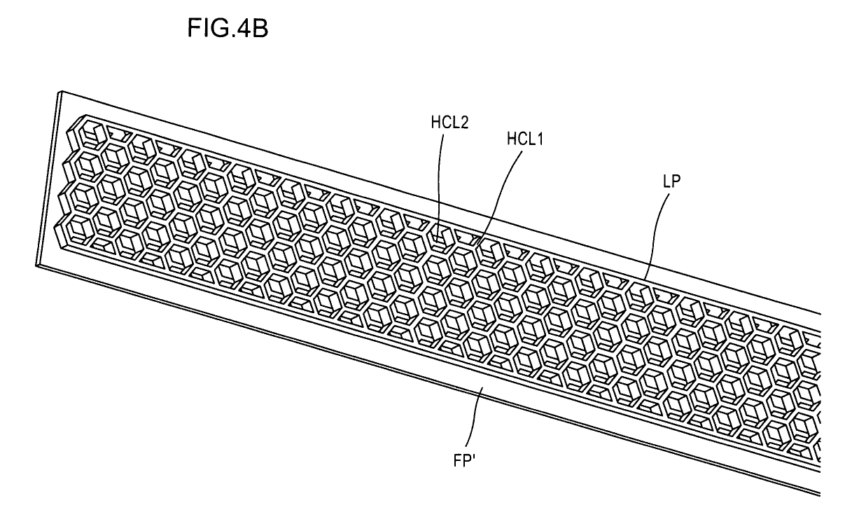

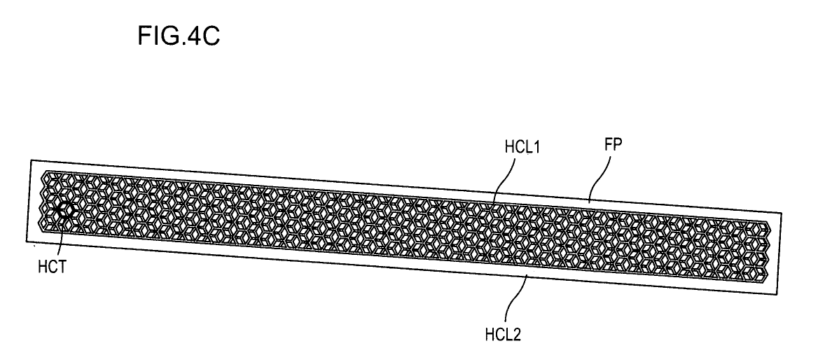

In a example shown in FIG. 2, the parallel hex shaped apertures have a 0.25 in. depth, a 0.20 in length, and 0.18 in outer wall thickness. The area of each hex is given by the equation: SQRT (3/2)*W², where W=2H. In the example on FIG. 4A, there are ˜228 hexagonal apertures, each with ˜0.035 in² area per Hex opening, therefore 7.98 in² of open area. The total area, not including the perimeter flange, is given by 11.62*0.908=10.6 in squared. Thus, the example in FIG. 4A yields an open area of 75%. This does not reflect the maximum open area available; however this would be a very reasonable implementation scenario. Although a greater SE performance is achieved with a waveguide of greater depth, the embodiment in the parent application requires a larger amount of polymer due to the greater depth of each tube and the independent structure of the tubular walls.

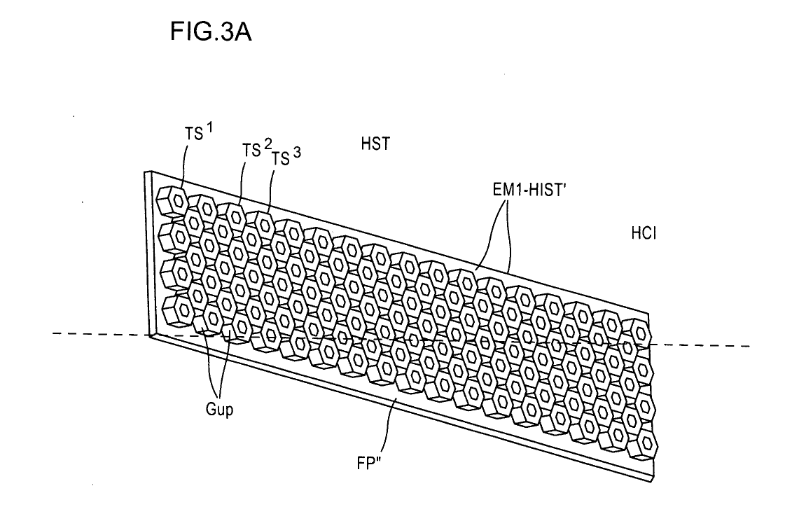

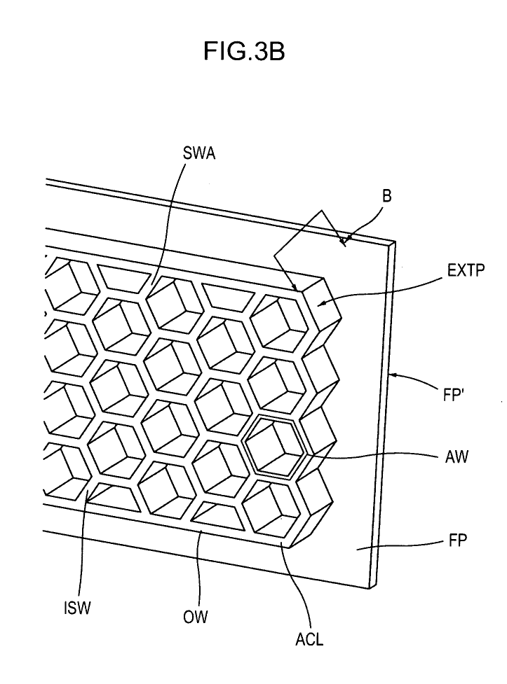

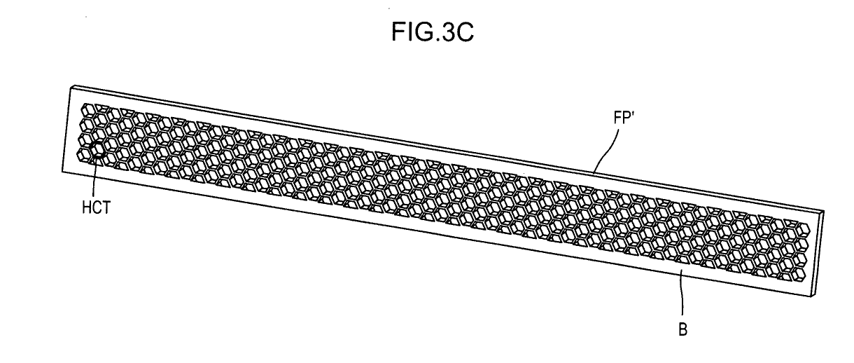

FIGS. 3A-3C shows what the embodiment described in parent application Ser. No. 11/770,736 would look like if the patterned tubes were to be “cut” off. This embodiment highlights the excess material used due to each “cut” patterned tube comprising its own outer wall. In the present design, as shown in FIG. 3B, the parallel hex shaped apertures enable each waveguide to share an outer wall with its neighboring waveguide, thus saving material and costs.

SE is maintained, thermal efficiency is improved and material costs are reduced in the present design by stacking the honeycomb shielding in a staggered pattern. As shown in FIG. 4A staggering honeycomb shielding produces “diamond shaped” apertures (from the direct front or rear perspective) with a smaller open area than the original hexagon shaped apertures. These smaller diamond shaped apertures have a smaller width, resulting in a higher cutoff frequency, increasing the EMI performance of the waveguide. This stacked staggered honeycomb pattern also increases the depth of the waveguides, retaining some of the decrease in SE when compared with the patterned tubular structures.

The honeycomb waveguides may be stacked, abutting directly against each other, or placed with a gap between each honeycomb waveguide. Two or more honeycomb waveguides may be stacked in a staggered pattern depending on the application.

The use of staggered parallel hexagonal waveguides increases the volume of airflow that reaches the electronic device when compared to independent patterned tubes. This is the result of a pressure drop trade-off with the decrease in aperture depth. Pressure drop is quantity of interest in the analysis of tube flow. The pressure drop (P) during the flow in a tube of length (L) is expressed as: P=f[(LpVₘ²)/(D2)], where f is the friction factor, Vₘ is the mean velocity of the air, p is the density of the air, and D is the diameter of the tube. As shown in the above equation there is a direct relationship between pressure drop from the entrance to the exit of a tube and the length of that tube. As a result, there is a decrease in pressure drop resulting in increased air flow as a result of a decrease in aperture depth.

Increasing open area percentage also reduces the pressure drop of the waveguide. Open area percentage is defined as the ratio of cross sectional area in the flow direction that is unobstructed (summation of the hole area) to the total cross sectional area of waveguide hole pattern (the total of area of holes plus material).

FIG. 3A illustrates an embodiment where “tubular” waveguides with independent structures that are molded into the front plate FP are “cut” off. The resulting waveguides, designated as EMI-HST, are in a honeycomb pattern extending back from the front plate FP. Each EMI-HST has its own tubular structure (TS). Each tubular structure TS of the resulting waveguides EMI-HST has a gap GP between adjoining waveguides EMI-HST with no waveguide EMI-HST sharing a wall with adjoining waveguides EMI-HST. This embodiment highlights the material wasted and increased manufacturing costs associated with waveguides that do not have shared walls.

FIGS. 3B-C, illustrate a “shared wall” embodiment in which “tubular” hexagonal waveguides HW are formed into the front plate FP in a honeycomb pattern to form a honeycomb layer HCL. Almost all of the hexagonal waveguides HW share a inner wall IW with another hexagonal waveguide HW. Thus providing the advantages of reducing the amount of (costly) material that must be used to both provide sufficient EMI shielding and allowing for thermal advantages. The resulting honeycomb layer formed from the honeycomb waveguides results in an outer wall OW which has a resulting exterior plate EXTP. The hexagonal waveguides extend back from the front of the front plate FP. The depth of the exterior face plate EXTP combined with the depth of the front plate FP results in the actual depth of the hexagonal waveguides HW.

FIGS. 4A to 4C illustrate a primary embodiment of the invention in a “staggered honeycomb” front plate FP. In general, the “stagger” is formed into two honeycomb layers HCL1 and HCL2 of the front plate FP, taking advantage of the EMI shielding capabilities (and structural) of the tubular hexagonal waveguides formed into the front plate FP in a honeycomb pattern made of conductive or coated polymer. Staggering the honeycomb layers reduces the size of the apertures by forming smaller waveguides APNW, APSW, and APE through the staggered stacking of hexagonal waveguides HW1 in honey comb layer 1 HCL1 and hexagonal waveguides HW2 in honeycomb layer 2 HCL2. Each of the resulting smaller waveguides APNW, APSW, and APE has a smaller diameter than the hexagonal waveguides HW1 and HW2, providing a higher cutoff frequency f_{c} and improved EMI shielding effectiveness.

The embodiment in FIGS. 4A to 4C also improve thermal flow through the waveguides. The use of staggered parallel hexagonal waveguides increases the volume of airflow that reaches the electronic device when compared to individual patterned tubes. This is the result of a pressure drop trade-off with the decrease in aperture depth. Pressure drop is quantity of interest in the analysis of tube flow. The pressure drop (P) during the flow in a tube of length (L) is expressed as: P=f[(LpVₘ²)/(D2)], where f is the friction factor, Vₘ is the mean velocity of the air, p is the density of the air, and D is the diameter of the tube. As shown in the above equation there is a direct relationship between pressure drop from the entrance to the exit of a tube and the length of that tube. As a result, there is a decrease in pressure drop resulting in increased air flow as a result of a decrease in aperture depth. Although the hexagonal waveguides in honeycomb layer 2 HCL2 is the preferred embodiment, elliptical waveguides may also be used in honeycomb layer 2 HCL2.

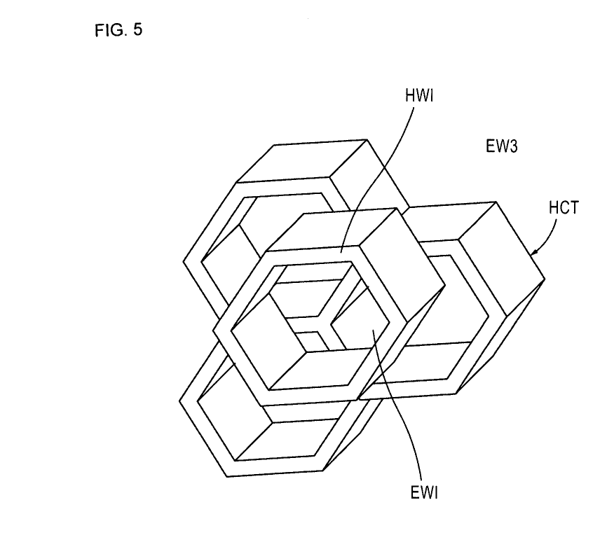

FIG. 5 highlights the behavior of electromagnetic waves as they enter and pass through hexagonal waveguides HW1 in honeycomb layer 1 HCL1 and then smaller waveguides APNW, APSW, and APE in honeycomb layer 2 HCL2. Electromagnetic waves EW1 initially entering into hexagonal waveguides HW1 will be attenuated by the hexagonal waveguides cutoff frequency f_{c}1, which is determined by the outside dimensions of the hexagonal waveguides HW1. After the electromagnetic waves EW1 pass through the hexagonal waveguides HW1, the resultant waves EW2 will have a waveguide with frequencies lower than f_{c}1 greatly attenuated. These resultant waves EW2 will then enter into the smaller waveguides (APNW, APSW, and APE) and will be further attenuated by the smaller waveguides cutoff frequency f_{c}2, which is greater than f_{c}1. The resultant electromagnetic wave EW3 will have all but frequencies greater than f_{c}2 greatly attenuated. EMI is thus greatly reduced while reducing material cost and maintaining a large open area that does overly restrict air flow.

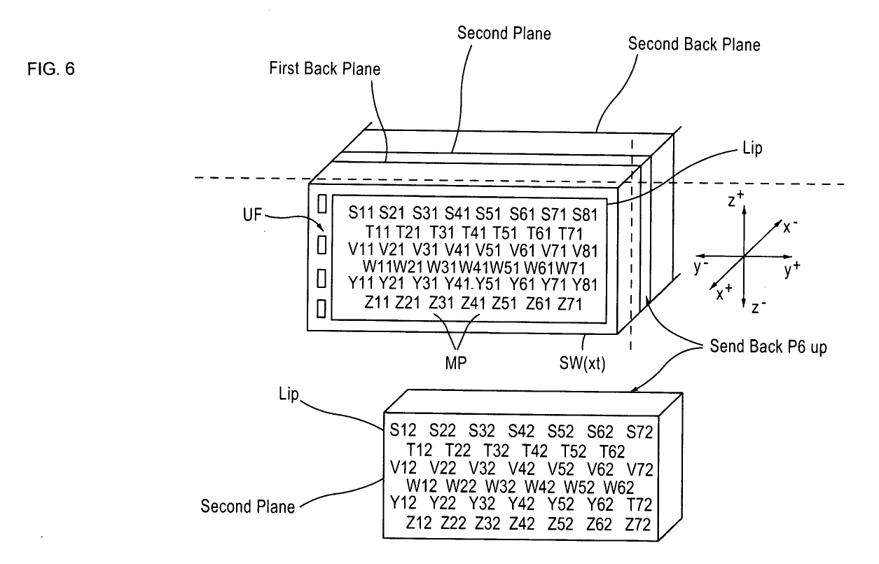

FIG. 6 illustrates alternate embodiments of the “staggered honeycomb” in which the EMI shielding is improved (through a reduction in apertures) using various features. These features are discussed in parent patent application Ser. No. 11/770,736, which is incorporated by reference.

Another embodiment of invention provides the computer box/front plate embodiment of the invention in which the front plate FP as shown and described above in FIGS. 3a-6 in placed in one or “windows” of a six-sides (metal) or conductive enclosure. In general, the various configurations of a front plate FPX are placed into a “window” of one or more sides of a conductive (usually metal) enclosure MENC. The front plate FPX is electrically connected to the metal enclosure MENC at contact points EC (which are not shown in detail), which are small “leaf spring” contacts in one configuration (which may be made of the metal or the conductive or coated or layered polymer). The various configurations of the front plate FPX provides both ventilation and EMI shielding to the electronics in the interior.

Various embodiments of the invention may be configured in ways other than have been illustrated above, without departing from the scope and spirit of invention, nor is the present invention limited to computer components that require EMI shielding. The present invention is directed at reducing or eliminating the need for cumbersome and problematic EMI gasketting while increasing thermal efficiency through the use of innovative configuration of materials that help reduce the cost of manufacture and assembly. Those skilled in the art should consider the claims recited below as defining the scope of the invention and not the above demonstrative examples, which are provided for illustrative purposes.

I claim:

1. A front plate for an electronics enclosure that provides improved electromagnetic interference (EMI) shielding, said front plate made of a shielding polymer and in electrical contact with a partial conductive metal enclosure;
said front plate having a front plane and a rear plane, and configured to provide interior access to said enclosure with a first set of tubes, said first set of tubes formed into said front plate and extending from said front plane to at least said rear plane such that said first set of tubes reaches said interior of said enclosure, wherein said set of tubes includes individual tubes structures that share a partial adjoining wall with another individual tube.

2. The shielding unit as recited in claim 1, wherein said shielding polymer includes nickel-plated carbon fibers.

3. The shielding unit as recited in claim 1, wherein said shielding polymer is coated with a shielding material.

4. The shielding device as recited in claim 1, wherein said first set of tubes are circular, square, hexagonal, pentagons, or octagons.

5. The shielding device as recited in claim 1, have a length to thickness ratio of at least 10.

6. The shielding device as recited in claim 1, wherein said shielding device is a single piece of molded plastic.

7. The shielding device as recited in claim 1, wherein said shielding device having at least a second set of tubes arranged in a similar manner as said first set of tubes and stacked in a staggered fashion on the rear plane side of said first set of tubes.

8. The shielding device recited in claim 7, wherein said second set of tubes are circular, square, hexagonal, pentagons, or octagons.

9. An electronics enclosure formed from a five-sided enclosure and a front plate in electrical contact with said five-sided enclosure, said front plate made of a conductive-coated or conductive polymer, including: said front plate including a first set of hexagonal shapes formed into a front side of said at least one side, wherein said set of shapes extend into an interior of an enclosure, and terminate before a plane formed by the rear wall of said at least one side, and a second set of hexagonal shapes formed an auxiliary wall located behind said termination of said first set of hexagonal shapes, and said shapes extending into said interior of said enclosure extending behind said plane formed by said rear wall, a gap being included between said first and said second set of hexagonal shapes.

10. The shielding unit as recited in claim 9, wherein said shielding polymer includes nickel-plated carbon fibers.

11. The shielding unit as recited in claim 9, wherein said shielding polymer is coated with a shielding material.

12. The shielding device as recited in claim 9, wherein said first set of tubes are circular, square, hexagonal, pentagons, or octagons.

13. The shielding device as recited in claim 9, having a length to thickness ratio of at least 10 in the first set of hexagons.
